(19) United States
(12) Patent Application Publication
(10) Pub. No.: US 2026/0150471 A1
(43) Pub. Date: May 28, 2026

(54) WINDOW, METHOD OF MANUFACTURING WINDOW, AND ELECTRONIC DEVICE INCLUDING WINDOW

(71) Applicant: Samsung Display Co., LTD., Yongin-si (KR)

(72) Inventors: SANGHOON KIM, Yongin-si (KR); SEONGJIN HWANG, Yongin-si (KR); BYUNGHOON KANG, Yongin-si (KR); SEUNGHO KIM, Yongin-si (KR); JINGYU SIM, Yongin-si (KR)

(21) Appl. No.: 19/265,735

(22) Filed: Jul. 10, 2025

(30) Foreign Application Priority Data
Nov. 27, 2024 (KR) 10-2024-0171811

(51) Int. Cl. H10H 29/853; C03C 17/32

(52) U.S. Cl. CPC H10H 29/853; C03C 17/322; C03C 17/326

(57) ABSTRACT

A window is divided into a folding area, a first non-folding area, and a second non-folding area. The window includes a coating layer, a glass substrate, and a pattern part. The coating layer has a first Young's modulus. The glass substrate includes a first portion, a second portion, and a third portion having a thickness smaller than that of the first portion and the second portion and disposed on the coating layer. The pattern part is disposed between the coating layer and the glass substrate, overlaps the folding area, and has a second Young's modulus greater than the first Young's modulus.

This application claims priority to Korean Patent Application No. 10-2024-0171811, filed on Nov. 27, 2024, and all the benefits accruing therefrom under 35 U.S.C. § 119, the content of which in its entirety is herein incorporated by reference.

### BACKGROUND

### 1. Field

Embodiments of the disclosure described herein relate to a foldable window, a method of manufacturing the window, and an electronic device including the window, and more particularly, relate to a window including a pattern part, a method of manufacturing the window, and an electronic device including the window.

### 2. Description of the Related Art

Various types of electronic devices are used to provide image information, and electronic devices including foldable or bendable flexible display panels have recently been developed. Unlike rigid electronic devices, the flexible electronic devices may be variously changed in shape, for example, may be folded, rolled, or bent, and thus may be carried regardless of a size of a displayed screen.

A window for protecting a display panel or the like is desired in the flexible electronic devices without hindering a folding or bending operation.

### SUMMARY

Embodiments of the disclosure provide a window exhibiting excellent impact resistance and an electronic device including the window.

Embodiments of the disclosure also provide a method of manufacturing a window exhibiting excellent impact resistance.

In an embodiment, a window is divided into a folding area, a first non-folding area next (adjacent) to one side of the folding area, and a second non-folding area next (adjacent) to an opposite side of the folding area opposite to the one side of the folding area, the window including a coating layer having a first Young's modulus, a glass substrate including a first portion overlapping the first non-folding area, a second portion overlapping the second non-folding area, and a third portion overlapping the folding area and having a thickness smaller than that of the first portion and the second portion, and disposed on the coating layer, and a pattern part disposed between the coating layer and the glass substrate, overlapping the folding area, and having a second Young's modulus greater than the first Young's modulus, where the pattern part includes a plurality of pattern portions spaced apart from each other in an one direction perpendicular to a thickness direction, and the pattern portions include a first pattern portion having a first length in the thickness direction and a second pattern portion having a second length greater than the first length and spaced apart from the first pattern portion in the direction.

The pattern part may not overlap the first non-folding area and the second non-folding area.

In an embodiment, the first pattern portion may be disposed outside the second pattern portion.

In an embodiment, an upper surface of each of the first pattern portion and the second pattern portion may contact the glass substrate.

In an embodiment, the coating layer may include a first coating portion extending in the direction and a second coating portion extending from the first coating portion and disposed to fill gaps between the plurality of pattern portions.

In an embodiment, the coating layer may further include a third coating portion extending from the first coating portion and disposed next (adjacent) to a side surface of the glass substrate.

In an embodiment, the window may further include a sub-pattern portion disposed on the coating layer and having the first Young's modulus, where the sub-pattern portion may be spaced apart from the pattern part in the direction with the glass substrate interposed therebetween.

In an embodiment, In a plan view, each of the plurality of pattern portions may have a circular shape, a polygonal shape, or a cross shape.

In an embodiment, the plurality of pattern portions may have an integral shape, and in a plan view, openings may be defined in the plurality of pattern portions.

In an embodiment, In a plan view, each of the plurality of pattern portions may have a curvature and extend in an other direction perpendicular to the direction.

In an embodiment, a width of each of the plurality of pattern portions in the direction may decrease as a distance from the glass substrate increases.

In an embodiment, the first Young's modulus of the coating layer may be greater than or equal to 0.1 gigapascal (GPa) and smaller than 1 GPa.

In an embodiment, the second Young's modulus of the pattern part may be greater than or equal to 1 GPa and smaller than or equal to 10 GPa.

In an embodiment, each of the pattern part and the coating layer may include at least one of a urethane acrylate-based resin, an epoxy-based resin, and a silicone-based resin.

In an embodiment, the coating layer may include an upper surface next (adjacent) to the glass substrate and a lower surface spaced apart from the glass substrate with the upper surface interposed therebetween, and the lower surface may be flat.

In an embodiment of the disclosure, a method of manufacturing a window divided into a folding area, a first non-folding area next (adjacent) to one side of the folding area, and a second non-folding area next (adjacent) to an opposite side of the folding area opposite to the one side of the folding area and including a coating layer, a glass substrate disposed on the coating layer, and a pattern part disposed between the coating layer and the glass substrate includes preparing a glass substrate including a first portion overlapping the first non-folding area, a second portion overlapping the second non-folding area, and a third portion overlapping the folding area and having a thickness smaller than those of the first portion and the second portion, forming a pattern part including a plurality of pattern portions by providing a first polymer resin onto the third portion, and forming the coating layer by providing a second polymer resin onto the glass substrate and the pattern part, where the plurality of pattern portions are spaced apart from each other in an one direction perpendicular to a thickness direction and includes a first pattern portion having a first length in the thickness direction and a second pattern portion having a second length smaller than the first length and spaced apart from the first pattern portion in the direction, and a second Young's modulus of the pattern part is greater than a first Young's modulus of the coating layer.

In an embodiment, the forming the pattern part may include patterning the first polymer resin provided on the third portion using a first mold.

In an embodiment, the forming the pattern part may include patterning the first polymer resin in an inkjet printing method.

In an embodiment, in the forming the coating layer, a second mold may be provided to the second polymer resin provided onto the glass substrate and the pattern part, and the coating layer may include an upper surface next (adjacent) to the glass substrate and a flat lower surface spaced apart from the glass substrate with the upper surface interposed therebetween.

In an embodiment of the disclosure, an electronic device includes a display module and a window divided into a folding area, a first non-folding area next (adjacent) to one side of the folding area, and a second non-folding area next (adjacent) to an opposite side of the folding area opposite to the one side of the folding area, and disposed on the display module, where the window includes a coating layer having a first Young's modulus, a glass substrate including a first portion overlapping the first non-folding area, a second portion overlapping the second non-folding area, and a third portion overlapping the folding area and having a thickness smaller than that of the first portion and the second portion, and disposed on the coating layer, and a pattern part disposed between the coating layer and the glass substrate, overlapping the folding area, and having a second Young's modulus greater than the first Young's modulus, where the pattern part includes a plurality of pattern portions spaced apart from each other in one direction perpendicular to a thickness direction, and the plurality of pattern portions include a first pattern portion having a first length in the thickness direction and a second pattern portion having a second length smaller than the first length and spaced apart from the first pattern portion in the direction.

### BRIEF DESCRIPTION OF THE DRAWINGS

The above and other embodiments, advantages and features of the

disclosure will become apparent by describing in detail embodiments thereof with reference to the accompanying drawings.

FIG. 1A is a perspective view illustrating an embodiment of an electronic device.

FIG. 1B is a perspective view illustrating an embodiment of the electronic device.

FIG. 1C is a plan view illustrating an embodiment of the electronic device.

FIG. 1D is a perspective view illustrating an embodiment of the electronic device.

FIG. 2A is a perspective view illustrating an embodiment of the electronic device.

FIG. 2B is a perspective view illustrating an embodiment of the electronic device.

FIG. 2C is a perspective view illustrating an embodiment of the electronic device.

FIG. 3 is an exploded perspective view illustrating an embodiment of the electronic device.

FIG. 4A is a cross-sectional view illustrating a portion corresponding to line I-I′ of FIG. 3.

FIG. 4B is a cross-sectional view illustrating an embodiment of a portion of the electronic device.

FIG. 5 is a cross-sectional view illustrating an embodiment of a window.

FIG. 6 is a cross-sectional view illustrating an embodiment of the window.

FIG. 7 is a cross-sectional view illustrating an embodiment of the window.

FIG. 8 is a perspective view illustrating an embodiment of a portion of the window.

FIG. 9A is a plan view illustrating an embodiment of a portion of the window.

FIG. 9B is a plan view illustrating an embodiment of a portion of the window.

FIG. 9C is a plan view illustrating an embodiment of a portion of the window.

FIG. 9D is a plan view illustrating an embodiment of a portion of the window.

FIG. 9E is a plan view illustrating an embodiment of a portion of the window.

FIG. 9F is a plan view illustrating an embodiment of a portion of the window.

FIG. 9G is a plan view illustrating an embodiment of a portion of the window.

FIG. 9H is a plan view illustrating an embodiment of a portion of the window.

FIG. 9I is a plan view illustrating an embodiment of a portion of the window.

FIG. 10A is a cross-sectional view illustrating an embodiment of a portion of the window.

FIG. 10B is a cross-sectional view illustrating an embodiment of a portion of the window.

FIG. 11 is a flowchart illustrating an embodiment of a method of manufacturing a window.

FIG. 12A is a schematic view illustrating an embodiment of an operation of manufacturing a window.

FIG. 12B is a schematic view illustrating an embodiment of the operation of manufacturing a window.

FIG. 12C is a schematic view illustrating an embodiment of the operation of manufacturing a window.

FIG. 13A is a schematic view illustrating an embodiment of the operation of manufacturing a window.

FIG. 13B is a schematic view illustrating an embodiment of the operation of manufacturing a window.

### DETAILED DESCRIPTION

Since the disclosure is variously modified and has various forms, an embodiment thereof will be illustrated in the drawings and will be described herein in detail. However, it should be understood that the disclosure is not limited to a specific disclosure and includes all changes, equivalents, and substitutes included in the spirit and scope of the disclosure.

In the specification, the expression that a first component (or an area, a layer, a part, a portion, etc.) is “disposed on”, “connected with” or “coupled to” a second component means that the first component is directly disposed on/connected with/coupled to the second component or means that a third component is interposed therebetween.

The same reference numerals refer to the same components. Further, in the drawings, the thickness, the ratio, and the dimension of components are exaggerated for effective description of technical contents. The term “and/or” includes all combinations of one or more components that may be defined by associated components.

Although the terms “first”, “second”, etc. may be used to describe various components, the components should not be limited by the terms. The terms are only used to distinguish one component from another component. For example, without departing from the right scope of the disclosure, a first component may be also referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the specification have the same meaning as commonly understood by those skilled in the art to which the disclosure belongs. Further, terms such as terms defined in the dictionaries commonly used should be interpreted as having a meaning consistent with the meaning in the context of the related technology and should not be interpreted in overly ideal or overly formal meanings unless explicitly defined herein.

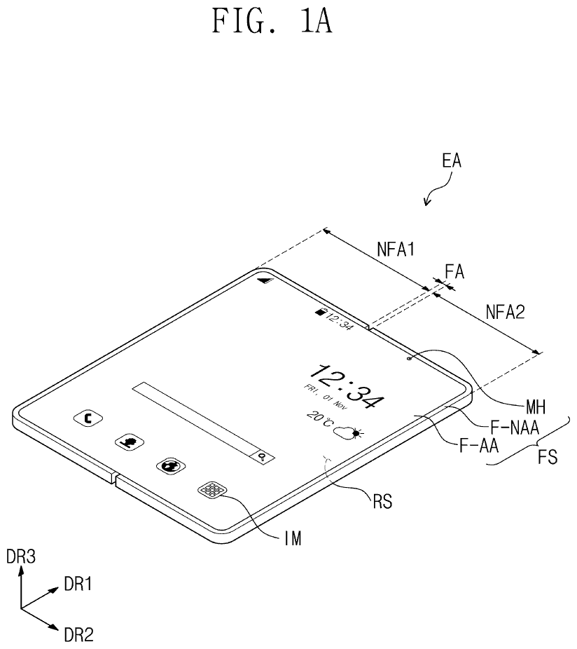

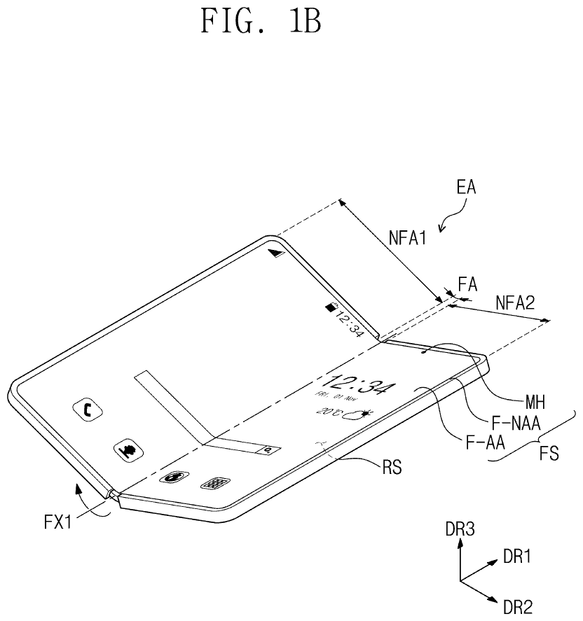

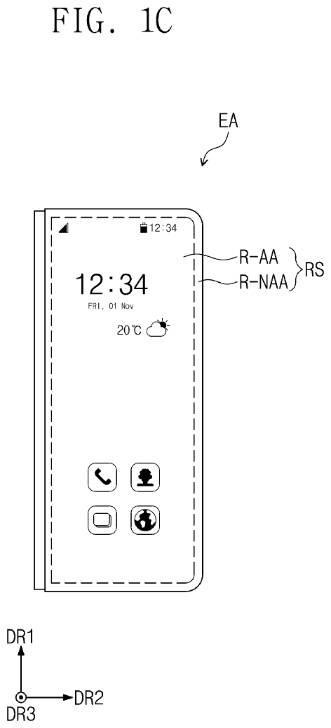

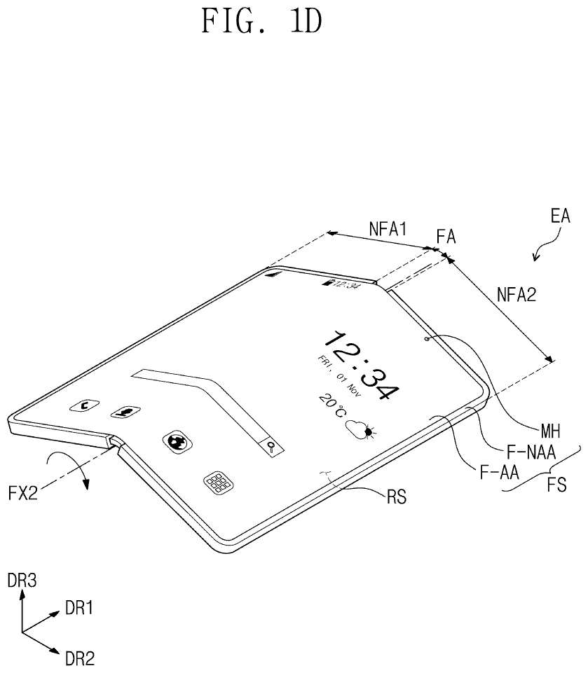

Hereinafter, a display device and an electronic device including the display device in an embodiment of the disclosure will be described with reference to the accompanying drawings. FIG. 1A is a perspective view of a state in which an electronic device EA in an embodiment is unfolded.

The electronic device EA in an embodiment may be a device that is activated by an electrical signal. In an embodiment, the electronic device EA may be a smartphone, a tablet computer, a vehicle navigation system, a game console, or a wearable device, but the disclosure is not limited thereto. FIG. 1A or the like illustrate that the electronic device EA is a smartphone.

The electronic device EA may include a first display surface FS defined by a first direction axis DR1 and a second direction axis DR2 intersecting the first direction axis DR1. The electronic device EA may provide an image IM to a user through the first display surface FS. The electronic device EA may display the image IM in a third direction axis DR3 to the first display surface FS parallel to the first direction axis DR1 and the second direction axis DR2. The image IM may include a dynamic image and a static image.

In the specification, the first direction axis DR1 and the second direction axis DR2 may be perpendicular to each other, and the third direction axis DR3 may be a normal direction to a plane defined by the first direction axis DR1 and the second direction axis DR2. A thickness direction of the electronic device EA may be a direction parallel to the third direction axis DR3. The thickness direction of the electronic device EA may use the same reference numeral as that of the third direction axis DR3. A front surface (or an upper surface) and a rear surface (or a lower surface) may be opposite to each other in the third direction axis DR3, and a normal direction of each of the front surface (or the upper surface) and the rear surface (or the lower surface) may be parallel to the third direction axis DR3. The front surface (or the upper surface) means a surface next (adjacent) to the first display surface FS, and the rear surface (or the lower surface) means a surface spaced apart from the first display surface FS. Further, the rear surface (or the lower surface) means a surface close to a second display surface RS, which will be described below. An upper side means a direction closer to the first display surface FS, and a lower side means a direction away from the first display surface FS.

A cross section means a surface parallel to the third direction axis (hereinafter, also referred to as a third direction) DR3, and a plane means a surface perpendicular to the third direction DR3. The plane means a surface parallel to the plane defined by the first direction axis DR1 and the second direction axis DR2.

The directions indicated by the first direction axis DR1, the second direction axis DR2, and the third direction axis DR3 are relative concepts and may be changed to other directions. Further, directions indicated by the first direction axis DR1, the second direction axis DR2, and the third direction axis DR3 may be described as a first direction, a second direction, and a third direction, and the same reference numerals may be used therefor.

The electronic device EA may sense an external input applied from the outside. The external input may include various types of inputs provided from the outside of the electronic device EA. In an embodiment, the external input may include a contact by a part of a body of the user such as a hand as well as an external input (e.g., hovering) applied close to the electronic device EA or next (adjacent) to the electronic device EA at a predetermined distance. Further, the external input may have various forms such as a force, a pressure, a temperature, and light.

The electronic device EA may include the first display surface FS and the second display surface RS. The first display surface FS may include a first active area F-AA, a first peripheral area F-NAA, and a sub-area MH. The second display surface RS may be defined as a surface facing at least a portion of the first display surface FS. That is, the second display surface RS may be defined as a portion of the rear surface of the electronic device EA.

The first active area F-AA may be an area that is activated according to an electrical signal. The first active area F-AA may be an area in which the image IM is displayed and various forms of external inputs may be sensed.

The first peripheral area F-NAA may be next (adjacent) to the first active area F-AA. A light transmittance of the first peripheral area F-NAA may be lower than a light transmittance of the first active area F-AA. The first peripheral area F-NAA may have a predetermined color. The first peripheral area F-NAA may surround the first active area F-AA. Accordingly, a shape of the first active area F-AA may be defined substantially by the first peripheral area F-NAA. However, this is merely one of embodiments, and the first peripheral area F-NAA may be disposed next (adjacent) to only one side of the first active area F-AA or may be omitted.

The sub-area MH may sense an external subject received through the display surfaces FS and RS or provide a sound signal such as voice to the outside through the display surfaces FS and RS. An optical signal such as visible light or infrared light may move to the sub-area MH.

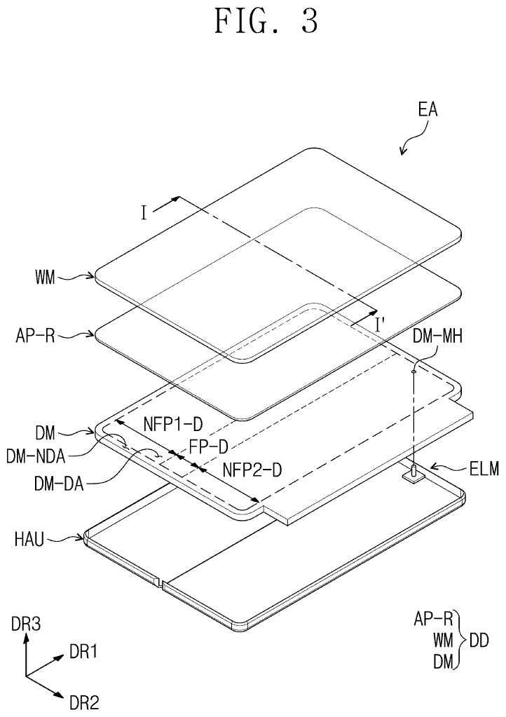

Various electronic modules ELM (refer to FIG. 3) may be arranged to correspond to the sub-area MH. In an embodiment, the electronic module ELM (refer to FIG. 3) may include at least one of a camera, a speaker, a light sensing sensor, and a heat sensing sensor. The electronic device EA may include the electronic module ELM (refer to FIG. 3) that photographs an external image through visible light passing through the sub-area MH or determines accessibility of an external object through infrared light. The electronic module ELM (refer to FIG. 3) may include a plurality of components, and is not limited to an embodiment.

The sub-area MH may be disposed inside the first active area F-AA. However, this is merely one of embodiments, and the disclosure is not limited thereto. In an embodiment, the sub-area MH may be surrounded by the first peripheral area F-NAA or may be surrounded by the first active area F-AA and the first peripheral area F-NAA. FIG. 1A or the like illustrate one sub-area MH, but the sub-area MH may be provided as a plurality of sub-areas MH.

The electronic device EA in an embodiment may include at least one folding area FA and a plurality of non-folding areas NFA1 and NFA2 extending from the folding area FA. In an embodiment, the first non-folding area NFA1, the folding area FA, and the second non-folding area NFA2 may be defined in the second direction axis (hereafter also referred to as a second direction) DR2.

The electronic device EA may include the first non-folding area NFA1 and the second non-folding area NFA2 spaced apart from each other in the second direction DR2 with the folding area FA interposed therebetween. In an embodiment, the first non-folding area NFA1 may be disposed on one side of the folding area FA in the second direction DR2, and the second non-folding area NFA2 may be disposed on an opposite side of the folding area FA opposite to the one side of the folding area FA in the second direction DR2.

FIG. 1A or the like illustrate an embodiment of the electronic device EA including the one folding area FA, but the disclosure is not limited thereto, and a plurality of folding areas may be defined in the electronic device EA. In an embodiment, the electronic device in an embodiment may include two or more folding areas and may include three or more non-folding areas arranged with the folding areas interposed therebetween.

FIG. 1B is a perspective view illustrating an embodiment of a folding operation of the electronic device EA. FIG. 1C is a plan view of an embodiment of a state in which the electronic device EA is folded. FIG. 1D is a perspective view illustrating an embodiment of a folding operation of the electronic device EA.

Referring to FIG. 1B, the electronic device EA in an embodiment may be folded about a first folding axis FX1 extending in the first direction axis (hereinafter also referred to as a first direction) DR1. In a state in which the electronic device EA is folded, the folding area FA may have a predetermined curvature and a predetermined radius of curvature. The electronic device EA may be folded about the first folding axis FX1 so that the first non-folding area NFA1 and the second non-folding area NFA2 face each other and may be changed into an in-folding state to prevent the first display surface FS from being exposed to the outside.

FIG. 1C may be a plan view illustrating the electronic device EA in an in-folded state. Referring to FIG. 1C, in a state in which the electronic device EA in an embodiment is in an in-folding state, the second display surface RS may be visually recognized by a user. In this case, the second display surface RS may include a second active area R-AA that displays an image. The second active area R-AA may be an area that is activated according to an electrical signal. The second active area R-AA may be an area on which an image is displayed and various types of external inputs may be sensed.

A second peripheral area R-NAA may be next (adjacent) to the second active area R-AA. A light transmittance of the second peripheral area R-NAA may be lower than a light transmittance of the second active area R-AA. The second peripheral area R-NAA may have a predetermined color. The second peripheral area R-NAA may surround the second active area R-AA. Although not illustrated, the electronic device EA may further include a sub-area in which an electronic module including various components is disposed even on the second display surface RS, but the disclosure is not limited to an embodiment.

Referring to FIG. 1D, the electronic device EA in an embodiment may be folded about a second folding axis FX2 extending in the first direction DR1. The electronic device EA may be folded about the second folding axis FX2 and changed into an out-folding state so that the first display surface FS is exposed to the outside. In an embodiment, the electronic device EA may mutually repeat an in-folding operation or an out-folding operation from an unfolding operation, but the disclosure is not limited thereto.

Although FIGS. 1A to 1D illustrate an embodiment of the folding about the one folding axis FX1 or FX2, in the electronic device EA, the number of folding axes and the number of non-folding areas according thereto are not limited thereto. In an embodiment, the electronic device EA may be folded about a plurality of folding axes so that the first display surface FS and the second display surface RS are folded to partially face each other. Further, it is illustrated that the first folding axis FX1 and the second folding axis FX2 are parallel to long sides of the electronic device EA, but the disclosure is not limited thereto, and the first folding axis FX1 and the second folding axis FX2 may be parallel to short sides of the electronic device EA.

In the electronic device EA, as illustrated in FIG. 1A or the like, the first non-folding area NFA1 and the second non-folding area NFA2 may be defined as portions having the display surfaces FS and RS parallel to the plane defined by the first direction axis DR1 and the second direction axis DR2 in a folded state, and the folding area FA may be defined as an area between the first non-folding area NFA1 and the second non-folding area NFA2. The folding area FA may include a curved surface that is curved to have a predetermined curvature in a folded state.

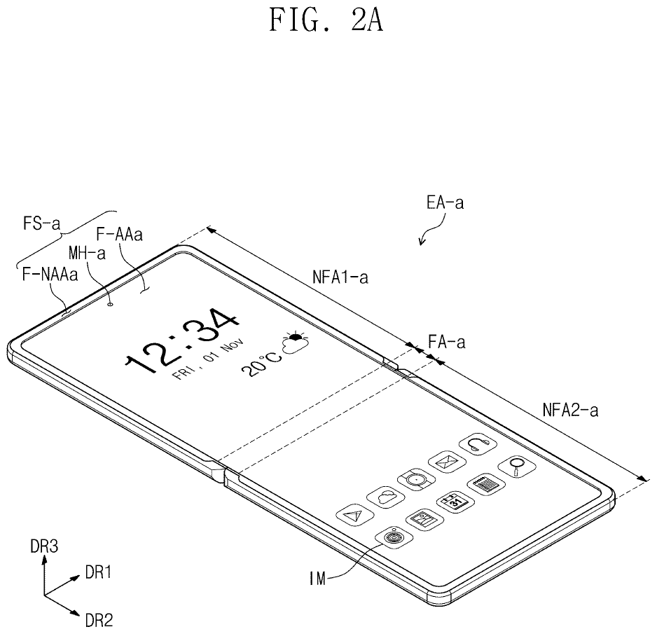

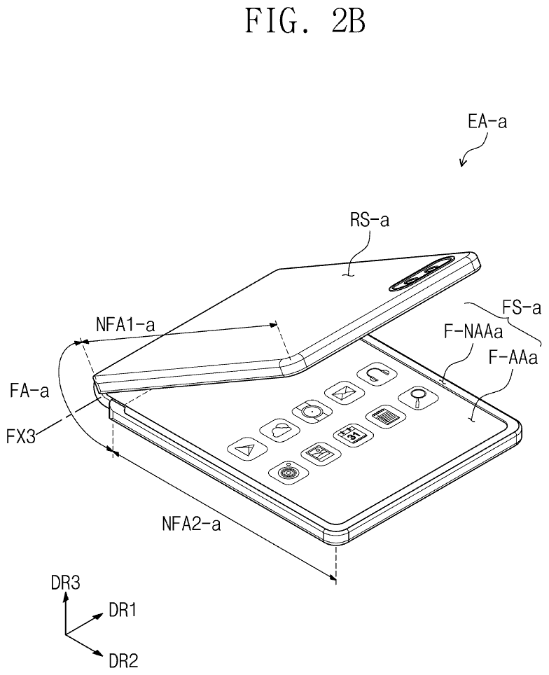

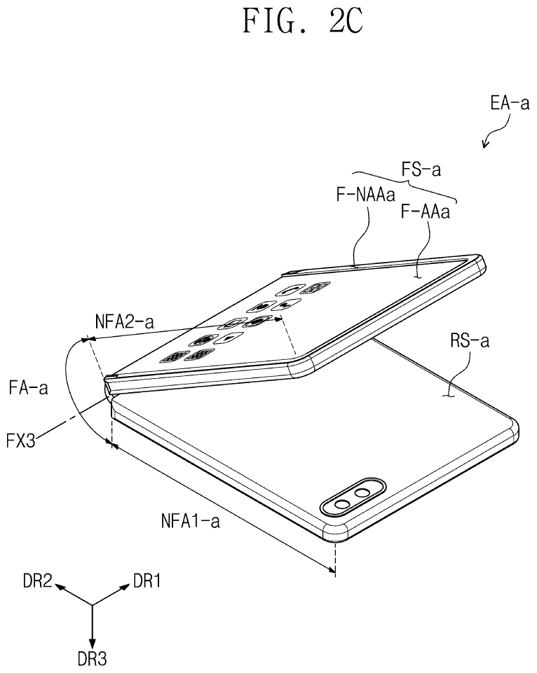

FIGS. 2A to 2C are perspective views illustrating an embodiment of an electronic device EA-a. FIG. 2A is a perspective view illustrating an unfolded state of the electronic device EA-a. FIGS. 2B and 2C are perspective views illustrating an folding operation of the electronic device EA-a. FIG. 2B is a perspective view illustrating an in-folding operation of the electronic device EA-a illustrated in FIG. 2A. FIG. 2C is a perspective view illustrating an out-folding operation of the electronic device EA-a illustrated in FIG. 2A.

The electronic device EA-a may be folded about a third folding axis FX3 parallel to the first direction axis DR1. Referring to FIGS. 2B and 2C, an extension direction of the third folding axis FX3 may be parallel to an extension direction of the short sides of the electronic device EA-a.

The electronic device EA-a may be divided into a folding area FA-a, a first non-folding area NFA1-a next (adjacent) to one side of the folding area FA-a, and a second non-folding area NFA2-a next (adjacent) to an opposite side of the folding area FA-a opposite to the one side of the folding area FA-a. The first non-folding area NFA1-a and the second non-folding area NFA2-a may be spaced apart from each other with the folding area FA-a interposed therebetween.

The folding area FA-a may be an area folded about the third folding axis FX3. In a state in which the electronic device EA-a is folded, the folding area FA-a may have a predetermined curvature and a predetermined radius of curvature. The first non-folding area NFA1-a and the second non-folding area NFA2-a may face each other, and the electronic device EA-a may be in-folded to prevent a display surface FS-a from being exposed to the outside.

Referring to FIG. 2A, in an embodiment, in a state in which the electronic device EA-a is in an unfolded state (i.e., a non-folded state), the display surface FS-a may be visually recognized by the user. As described with reference to FIGS. 1A to 1D, the display surface FS-a of the electronic device EA-a may include an active area F-AAa, a peripheral area F-NAAa, and a sub-area MH-a. The active area F-AAa may be an area in which the image IM is displayed and various forms of external inputs may be sensed.

Referring to FIG. 2B, in an embodiment of a state in which the electronic device EA-a is in-folded, a rear surface RS-a may be visually recognized by the user. In an embodiment, the rear surface RS-a may function as a second display surface that displays an image. Further, the sub-area in which an electronic module including various components is disposed may also be provided on the rear surface RS-a.

Referring to FIG. 2C, the electronic device EA-a may be folded about the third folding axis FX3 and changed into an out-folding state in which one area of the rear surface RS-a overlapping the first non-folding area NFA1-a and a remaining (the other) area of the rear surface RS-a overlapping the second non-folding area NFA2-a face each other.

FIG. 3 is an exploded perspective view of the electronic device EA illustrated in FIG. 1A. Hereinafter, a description of the electronic device EA may be equally applied to the electronic device EA-a illustrated in FIGS. 2A to 2C.

FIG. 3 is an exploded perspective view illustrating an embodiment of the electronic device EA. Referring to FIG. 3, the electronic device EA may include the electronic module ELM and a display device DD. Further, the electronic device EA may further include a housing HAU. In an embodiment, the display device DD may include a display module DM and a window WM disposed on the display module DM. A module area DM-MH may be defined in the display device DD, and the electronic module ELM may be disposed to correspond to the module area DM-MH.

The image IM (refer to FIG. 1A) generated in the display module DM may be provided to the user through the window WM. The window WM may be folded about at least one folding axis FX1 and FX2 (refer to FIGS. 1B and 1D).

The display device DD may further include an upper adhesive layer AP-R. The upper adhesive layer AP-R may be disposed between the display module DM and the window WM. The display module DM and the window WM may be coupled to each other through the upper adhesive layer AP-R. The upper adhesive layer AP-R may include a pressure sensitive adhesive (“PSA”), an optically clear adhesive film (“OCA”), or an optically clear adhesive resin layer (“OCR”). However, this is merely one of embodiments, and the disclosure is not limited thereto. Unlike the illustration, the upper adhesive layer AP-R may be omitted.

The display module DM may display an image according to an electrical signal and transmit/receive information on an external input. A display area DM-DA and a non-display area DM-NDA may be defined in the display module DM. Further, the module area DM-MH may be defined in the display module DM.

The display area DM-DA may be defined as an area that emits an image provided from the display module DM. The display area DM-DA of the display module DM may correspond to at least a portion of the first active area F-AA (refer to FIG. 1A).

A driving circuit, a driving wiring line, or the like for driving the display area DM-DA may be disposed in the non-display area DM-NDA. The non-display area DM-NDA may be next (adjacent) to the display area DM-DA. In an embodiment, the non-display area DM-NDA may surround the display area DM-DA. However, this is merely one of embodiments, the non-display area DM-NDA may be defined in various shapes, and the disclosure is not limited to an embodiment.

The module area DM-MH may correspond to the sub-area MH illustrated in FIG. 1A. An optical signal may move to the module area DM-MH. The module area DM-MH may be disposed inside the display area DM-DA. However, this is illustrative, and the disclosure is not limited to an embodiment.

The electronic module ELM may be disposed to correspond to the module area DM-MH. The electronic module ELM may be an electronic component that outputs or receives an optical signal. In an embodiment, the electronic module ELM may include a camera module and/or a proximity sensor. The camera module may capture an external image through the module area DM-MH. However, the disclosure is not limited thereto, and the electronic module ELM may further include a built-in module and/or an external module. The built-in module may include a sensor module, an antenna module, and an audio output module. The external module may include a light module and a communication module.

The display module DM may include a folding display part FP-D and non-folding display parts NFP1-D and NFP2-D. The folding display part FP-D may be a part corresponding to the folding area FA (refer to FIG. 1A), and the non-folding display parts NFP1-D and NFP2-D may be parts corresponding to the non-folding areas NFA1 and NFA2 (refer to FIG. 1A).

The housing HAU may include a material having a relatively high rigidity. In an embodiment, the housing HAU may include a plurality of frames and/or plates including or consisting of glass, plastic, or metal. The housing HAU may provide a predetermined accommodation space. The display module DM may be accommodated inside the accommodation space and protected from an external impact.

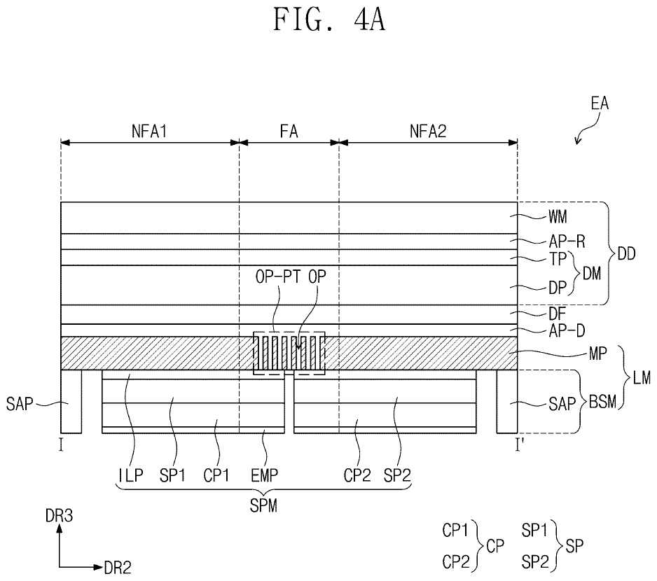

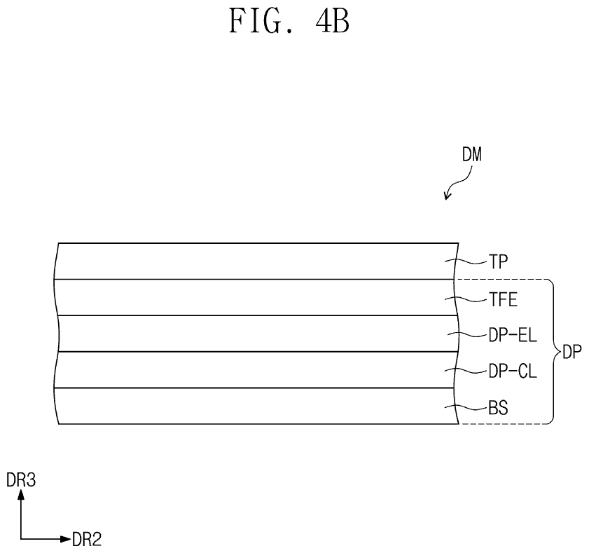

FIG. 4A is a cross-sectional view illustrating a portion corresponding to line I-I′ of FIG. 3. FIG. 4A may be a cross-sectional view illustrating the electronic device EA. In FIG. 4A, for convenience of description, the housing HAU (refer to FIG. 3) is omitted.

Referring to FIG. 4A, the electronic device EA may further include a lower module LM, a lower adhesive layer AP-D, and a lower protective film DF. The lower module LM, the lower adhesive layer AP-D, and the lower protective film DF may be arranged between the display device DD and the housing HAU (refer to FIG. 3).

The lower module LM may be disposed below the display module DM. The lower module LM may include a support plate MP and a lower support member BSM. A configuration of the lower module LM illustrated in FIG. 4A is exemplary, and a combination of components included in the lower module LM in the electronic device EA of an embodiment may be changed depending on a size of the electronic device EA, a shape of the electronic device EA, or operating characteristics of the electronic device EA.

The support plate MP may include a metal material or a polymer material. In an embodiment, the support plate MP may be formed to include stainless steel, aluminum, or any alloys thereof. Unlike this, the support plate MP may include or consist of a polymer material. A plurality of openings OP may be defined in the support plate MP. The support plate MP may include an opening pattern OP-PT in which the plurality of openings OP are defined. The opening pattern OP-PT may be formed in the folding area FA.

The lower support member BSM may include a support member SPM and a filling part SAP. In a plan view, the support member SPM may overlap most areas of the display module DM. The filling part SAP may be disposed outside the support member SPM and may overlap an exterior of the display module DM.

The support member SPM may include at least one of a support layer SP, a cushion layer CP, a shielding layer EMP, and an interlayer joining layer ILP. A configuration of the support member SPM illustrated in FIG. 4A is exemplary, and the disclosure is not limited thereto. In an embodiment, some of the support layer SP, the cushion layer CP, the shielding layer EMP, and the interlayer joining layer ILP may be omitted, a laminated order thereof may be modified to a different order from that of FIG. 4A, or an additional component other than the illustrated components may be further included in the support member SPM.

The support layer SP may include a metal material or a polymer material. The support layer SP may be disposed below the support plate MP. In an embodiment, the support layer SP may be a thin metal substrate. The support layer SP may include a first sub-support layer SP1 and a second sub-support layer SP2 spaced apart from each other in the second direction DR2. The first sub-support layer SP1 and the second sub-support layer SP2 may be spaced apart from each other in an area corresponding to the folding axes FX1 and FX2 (refer to FIGS. 1B and 1D). The support layer SP may be provided as the first sub-support layer SP1 and the second sub-support layer SP2 spaced apart from the folding area FA, thereby improving folding characteristics of the electronic device EA.

The cushion layer CP may be disposed under the support layer SP. The cushion layer CP may prevent a pressing phenomenon and plastic deformation of the support plate MP due to an external impact and an external force. The cushion layer CP may improve impact resistance of the electronic device EA. The cushion layer CP may include an elastomer such as sponge, foam, or urethane resin. Further, the cushion layer CP may be formed to include at least one of an acryl-based polymer, a urethane-based polymer, a silicone-based polymer, and an imide-based polymer. However, this is merely one of embodiments, and the disclosure is not limited thereto.

The cushion layer CP may include a first sub-cushion layer CP1 and a second sub-cushion layer CP2 spaced apart from each other in the second direction DR2. The first sub-cushion layer CP1 and the second sub-cushion layer CP2 may be spaced apart from each other in a portion corresponding to the folding axes FX1 and FX2 (refer to FIGS. 1B and 1D). The cushion layer CP may be provided as the first sub-cushion layer CP1 and the second sub-cushion layer CP2 spaced apart from the folding area FA, thereby improving folding characteristics of the electronic device EA.

The shielding layer EMP may be an electromagnetic wave shielding layer or a heat dissipating layer. Further, the shielding layer EMP may function as a joining layer.

The interlayer joining layer ILP may join components of the support plate MP and the support member SPM. The interlayer joining layer ILP may be provided in the form of a joining resin layer or an adhesive tape. FIG. 4A illustrates that the interlayer joining layer ILP is provided as two components spaced apart from each other in the area corresponding to the folding axes FX1 and FX2 (refer to FIGS. 1B and 1D), but the disclosure is not limited thereto. Unlike the illustration, the interlayer joining layer ILP may be provided as one layer not spaced apart from the area corresponding to the folding axes FX1 and FX2 (refer to FIGS. 1B and 1D).

The filling part SAP may be disposed outside the support layer SP and the cushion layer CP. The filling part SAP may be disposed between the support plate MP and the housing HAU (refer to FIG. 3). The filling part SAP may fill a space between the support plate MP and the housing HAU (refer to FIG. 3) and fix the support plate MP.

The lower protective film DF may be disposed between the display module DM and the support plate MP. The lower protective film DF may be a component disposed under the display module DM to protect a rear surface of the display module DM. The lower protective film DF may cover an entirety of the display module DM. The lower protective film DF may include a polymer material. In an embodiment, the lower protective film DF may be a polyimide film or a polyethylene terephthalate film. However, this is merely one of embodiments, and the lower protective film DF is not limited thereto.

The lower adhesive layer AP-D may be disposed between the support plate MP and the lower protective film DF. The support plate MP and the lower protective film DF may be coupled to each other through the lower adhesive layer AP-D. The lower adhesive layer AP-D may include a PSA, an OCA, or OCR. However, this is merely one of embodiments, and the disclosure is not limited thereto. Unlike the illustration, the lower adhesive layer AP-D may be omitted.

The display module DM may include a display panel DP and an input sensing unit TP disposed on the display panel DP. The display panel DP may be a component that substantially generates an image. The display panel DP in an embodiment may be folded with respect to the folding axes FX1 and FX2 (refer to FIGS. 1B and 1D).

The input sensing unit TP may sense an external input, convert the sensed external input into a predetermined input signal, and provide the input signal to the display panel DP. In an embodiment, the input sensing unit TP may be a touch sensing unit that senses a touch. The input sensing unit TP may recognize a direct touch of the user, an indirect touch of the user, a direct touch of an object, an indirect touch of the object, or the like.

The input sensing unit TP may sense at least one of a position and a strength (pressure) of a touch applied from the outside. In an embodiment, the input sensing unit TP may have various structures or may include or consist of various materials, and the disclosure is not limited to an embodiment. In an embodiment, the input sensing unit TP may sense an external input in a capacitive manner. The display panel DP may receive the input signal from the input sensing unit TP and generate an image corresponding to the input signal.

FIG. 4B may be a schematic cross-sectional view illustrating an embodiment of a configuration of the display module DM.

Referring to FIG. 4B, the display module DM may include the display panel DP and the input sensing unit TP disposed on the display panel DP. The display panel DP may be a component that substantially generates an image.

The display panel DP may include a base layer BS, a circuit layer DP-CL, a display element layer DP-EL, and an encapsulation layer TFE that are sequentially laminated. Unlike the illustration, a separate member may be further disposed between two layers next (adjacent) to each other among the base layer BS, the circuit layer DP-CL, the display element layer DP-EL, and the encapsulation layer TFE.

The base layer BS may provide a base surface on which the circuit layer DP-CL is disposed. The base layer BS may be a flexible substrate that may be bent, folded, and rolled. The base layer BS may be a glass substrate, a metal substrate, a polymer substrate, or the like. However, the disclosure is not limited thereto, and the base layer BS may include an inorganic layer, an organic layer, or a composite material layer.

The circuit layer DP-CL may be disposed on the base layer BS. The circuit layer DP-CL may include an insulating layer, a semiconductor pattern, a conductive pattern, a signal line, or the like. The display element layer DP-EL may be disposed on the circuit layer DP-CL. The display element layer DP-EL may include a light emitting element (not illustrated). In an embodiment, the light emitting element (not illustrated) may include an organic light emitting material, an inorganic light emitting material, an organic-inorganic light emitting material, a quantum dot, or a quantum rod. In an embodiment, the light emitting element (not illustrated) may include a micro light emitting diode (LED) or a nano LED.

The encapsulation layer TFE may be disposed on the display element layer DP-EL. The encapsulation layer TFE may protect the display element layer DP-EL from foreign substances such as moisture, oxygen, and dust particles. The encapsulation layer TFE may include at least one inorganic layer. In an embodiment, the encapsulation layer TFE may include an inorganic layer, an organic layer, and an inorganic layer which are sequentially laminated.

The input sensing unit TP may be disposed on the display panel DP. The input sensing unit TP may be directly disposed on the encapsulation layer TFE. Unlike this, an adhesive member may be disposed between the input sensing unit TP and the display panel DP.

In the specification, the fact that a first component is directly disposed/provided/formed on a second component means that a third component is not disposed/provided/formed between the first component and the second component. That is, the fact that a first component is directly disposed/provided/formed on a second component means that the first component contacts the second component.

The input sensing unit TP may sense an external input, convert the sensed external input into a predetermined input signal, and provide the input signal to the display panel DP. In an embodiment, the input sensing unit TP may be a touch sensing unit that senses a touch. The input sensing unit TP may recognize a direct touch of the user, an indirect touch of the user, a direct touch of an object, an indirect touch of the object, or the like.

The input sensing unit TP may sense at least one of a position and a strength (pressure) of a touch applied from the outside. In an embodiment, the input sensing unit TP may have various structures or may include or consist of various materials, and the disclosure is not limited to an embodiment. In an embodiment, the input sensing unit TP may sense an external input in a capacitive manner. The display panel DP may receive the input signal from the input sensing unit TP and generate an image corresponding to the input signal.

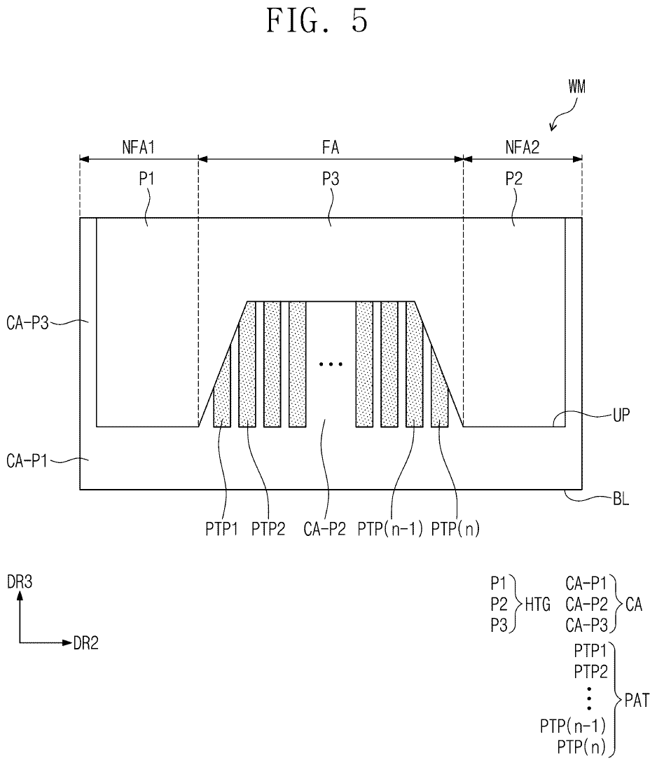

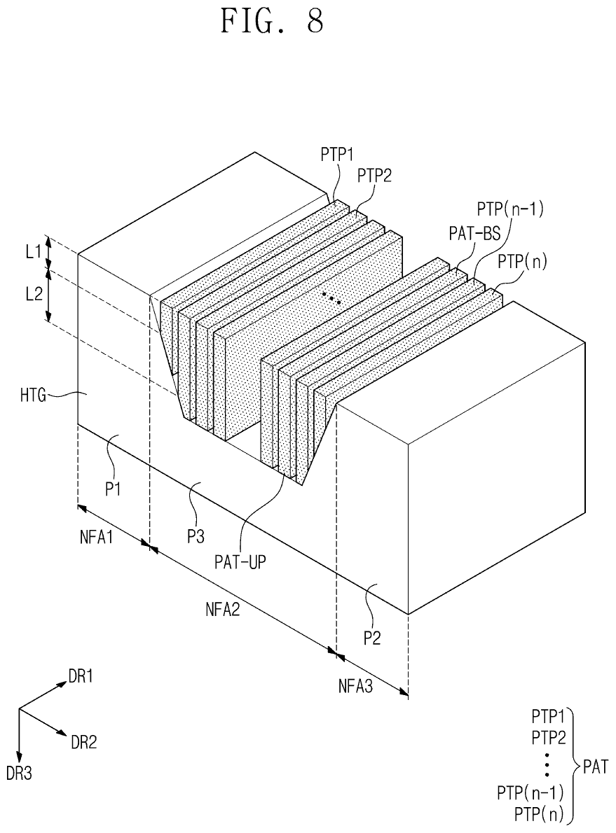

FIG. 5 is a cross-sectional view illustrating an embodiment of the window WM according to the disclosure. FIG. 8 is a perspective view illustrating an embodiment of a window and illustrates only some components configuration for convenience of description.

The window WM may be disposed on the display module DM (refer to FIG. 4A). The window WM may be divided into the folding area FA, the first non-folding area NFA1 next (adjacent) to one side of the folding area FA, and the second non-folding area NFA2 next (adjacent) to an opposite side of the folding area FA opposite to the one side of the folding area FA. The folding area FA, the first non-folding area NFA1, and the second non-folding area NFA2 of the window WM may be substantially the same as the folding area FA, the first non-folding area NFA1, and the second non-folding area NFA2 of the electronic device EA (refer to FIG. 1A). Hereinafter, the folding area FA, the first non-folding area NFA1, and the second non-folding area NFA2 of the window WM use substantially the same reference numerals as those of the folding area FA, the first non-folding area NFA1, and the second non-folding area NFA2 of the electronic device EA (refer to FIG. 1A).

The window WM may include a coating layer CA, a glass substrate HTG, and a pattern part PAT. The coating layer CA may include a first coating portion CA-P1 extending in the second direction DR2 and a second coating portion CA-P2 extending from the first coating portion CA-P1 and filled and disposed between a plurality of pattern portions PTP1, PTP2, . . . , PTP(n-1), PTP(n). Here, “n” is a natural number of two or more. In an embodiment, the coating layer CA may further include a third coating portion CA-P3 extending from the first coating portion CA-P1 and disposed next (adjacent) to a side surface of the glass substrate HTG. The third coating portion CA-P3 of the coating layer CA may be disposed to contact the side surface of the glass substrate HTG. In the coating layer CA, the third coating portion CA-P3 may be spaced apart from the second coating portion CA-P2 with a first portion P1 (or a second portion P2) of the glass substrate HTG interposed therebetween.

Young's modulus is a mechanical property that measures rigidity of a solid material and refers to a property of a material that resists elastic deformation. Thus, the Young's modulus may have a value that depends on physical properties of a material. The coating layer CA may have a first Young's modulus. The first Young's modulus of the coating layer CA may be greater than or equal to 0.1 gigapascal (GPa) and smaller than 1 GPa. The coating layer CA may include at least one of a urethane acrylate-based resin, an epoxy-based resin, and a silicone-based resin. The Young's modulus was measured at the room temperature.

The coating layer CA may include an upper surface UP next (adjacent) to the glass substrate HTG and a lower surface BL spaced apart from the glass substrate HTG with the upper surface UP interposed therebetween, and the lower surface BL may be a flat surface. The upper surface UP of the coating layer CA, which is next (adjacent) to the glass substrate HTG, may not be flat. The upper surface UP of the coating layer CA may contact the glass substrate HTG.

The glass substrate HTG may be disposed on the coating layer CA. The glass substrate HTG may include the first portion P1 overlapping the first non-folding area NFA1, the second portion P2 overlapping the second non-folding area NFA2, and a third portion P3 overlapping the folding area FA and having a thickness smaller than those of the first portion P1 and the second portion P2.

The pattern part PAT may be disposed between the coating layer CA and the glass substrate HTG. The pattern part PAT may overlap the folding area FA and may not overlap the first non-folding area NFA1 and the second non-folding area NFA2. A sum of a thickness of the pattern part PAT and the thickness of the third portion P3 of the glass substrate HTG may be substantially the same as the thickness of the first portion P1 (or the second portion P2) of the glass substrate HTG. In the specification, the wording “substantially the same” includes a case in which physical values are the same and a case in which there is a difference within an error range in a process.

The pattern part PAT may have a second Young's modulus that is greater than the first Young's modulus of the coating layer CA. The pattern part PAT having the relatively large second Young's modulus may prevent the glass substrate HTG from being deformed due to an external impact. The third portion P3 having a relatively thin thickness in the glass substrate HTG may be more vulnerable to an external impact than the first portion P1 and the second portion P2. The window WM in an embodiment may include the pattern part PAT disposed to overlap the third portion P3 of the glass substrate HTG to prevent the glass substrate HTG from being deformed due to an external impact.

The pattern part PAT may include the plurality of pattern portions PTP1, PTP2, . . . , PTP(n-1), PTP(n) that are spaced apart from each other in the second direction DR2 perpendicular to the third direction DR3. In an embodiment, n may be six. The plurality of pattern portions may include the first pattern portion PTP1 having a first length L1 (refer to FIG. 8) in the third direction DR3 and the second pattern portion PTP2 having a second length L2 (refer to FIG. 8) greater than the first length L1 (refer to FIG. 8) and spaced apart from the first pattern portion PTP1 in the second direction DR2.

The first length L1 (refer to FIG. 8) and the second length L2 (refer to FIG. 8) may be lengths parallel to the plurality of pattern portions PTP1, PTP2, . . . , PTP(n-1), PTP(n) in the third direction DR3. The first length L1 (refer to FIG. 8) and the second length L2 (refer to FIG. 8) may be minimum lengths parallel to the plurality of pattern portions PTP1, PTP2, . . . , PTP(n-1), PTP(n) in the third direction DR3.

The first pattern portion PTP1 may be disposed outside the second pattern portion PTP2. Upper surfaces PAT-UP (refer to FIG. 8) of the first pattern portion PTP1 and the second pattern portion PTP2 may contact the glass substrate HTG.

The second Young's modulus of the pattern part PAT may be greater than or equal to 1 GPa and smaller than or equal to 10 GPa. The pattern part PAT having the second Young's modulus smaller than 1 GPa may not prevent the glass substrate HTG from being deformed due to an external impact. The pattern part PAT having the second Young's modulus greater than 10 GPa is not easily repeatedly folded and unfolded. Unlike this, the pattern part PAT in an embodiment may have the second Young's modulus that is greater than or equal to 1 GPa and smaller than or equal to 10 GPa, thus exhibit excellent impact resistance, and exhibit characteristics in which the pattern part PAT is easily repeatedly folded and unfolded.

The pattern part PAT may include at least one of a urethane acrylate-based resin, an epoxy-based resin, and a silicone-based resin. The pattern part PAT and the coating layer CA may include different materials from each other.

A bottom surface PAT-BS (refer to FIG. 8) of the pattern part PAT may be disposed on the same plane as the upper surface UP of the coating layer CA.

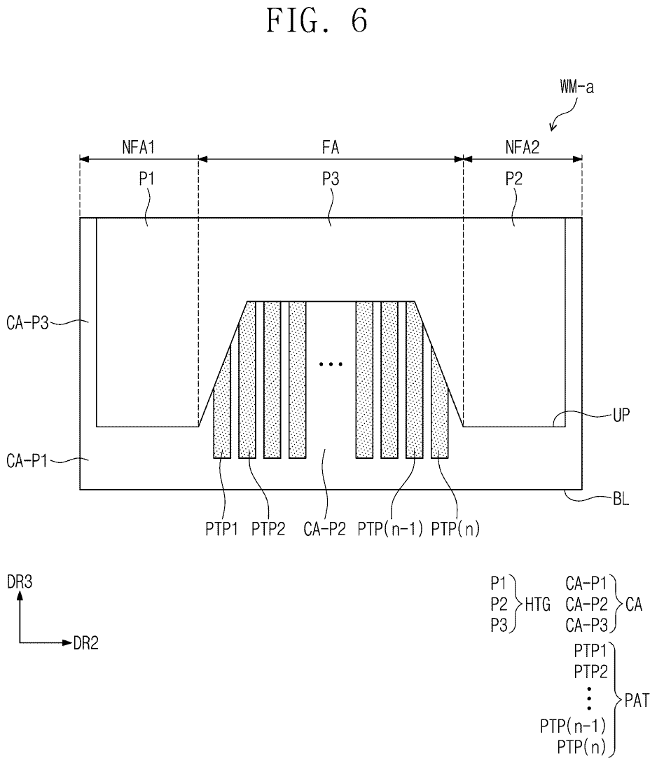

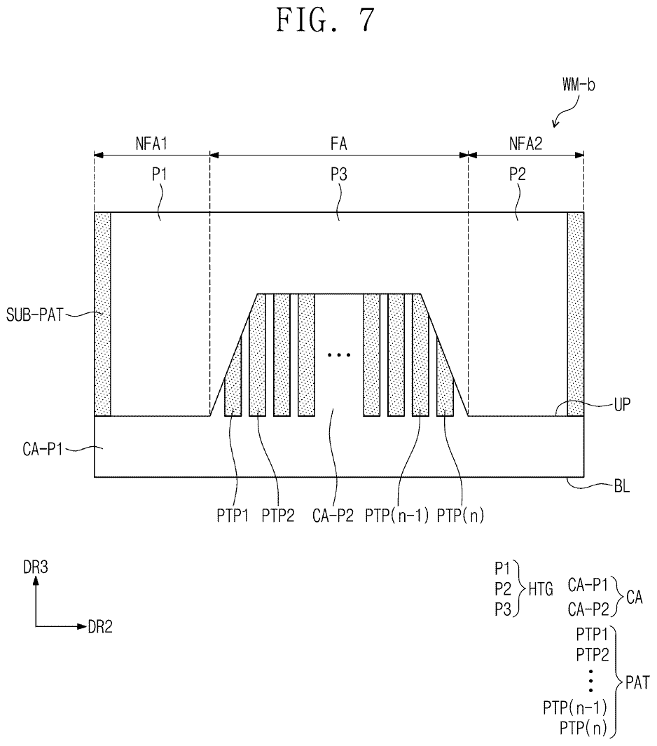

FIGS. 6 and 7 are cross-sectional views of an embodiment of windows WM-a and WM-b according to the disclosure. In description of FIGS. 6 and 7, contents duplicated with the contents described with reference to FIGS. 1A to 5 will not be described again, and differences will be mainly described.

FIG. 6 is different from FIG. 5 in that the bottom surface PAT-BS (refer to FIG. 8) of the pattern part PAT is disposed on a different plane from the upper surface UP of the coating layer CA. The bottom surface PAT-BS (refer to FIG. 8) of the pattern part PAT may be disposed below the upper surface UP of the coating layer CA. Although not illustrated, the bottom surface PAT-BS (refer to FIG. 8) of the pattern part PAT may be disposed above the upper surface UP of the coating layer CA.

FIG. 7 is different from FIG. 5 in that the window WM-b illustrated in FIG. 7 further includes a sub-pattern portion SUB-PAT disposed on the coating layer CA and having the first Young's modulus. The sub-pattern portion SUB-PAT may be spaced apart from the pattern part PAT with the glass substrate HTG interposed therebetween in the second direction DR2. The sub-pattern portion SUB-PAT may be disposed next (adjacent) to the side surface of the glass substrate HTG. The sub-pattern portion SUB-PAT may contact the side surface of the glass substrate HTG. The Young's modulus of the sub-pattern portion SUB-PAT may be substantially the same as the Young's modulus of the pattern part PAT. The sub-pattern portion SUB-PAT having a relatively high Young's modulus may be disposed next (adjacent) to the side surface of the glass substrate HTG to protect the glass substrate HTG from an external impact.

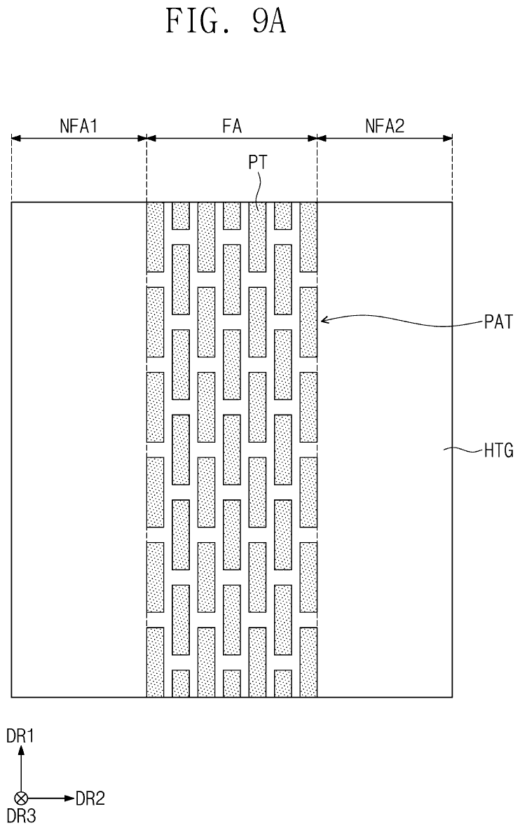

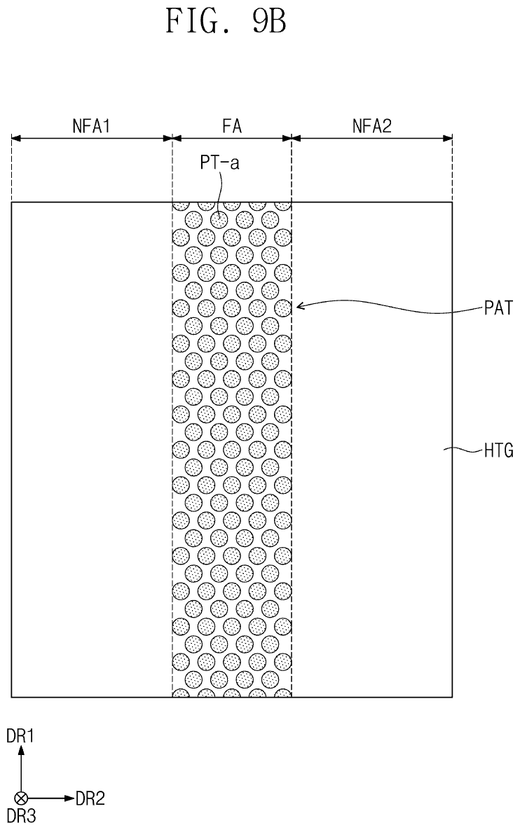

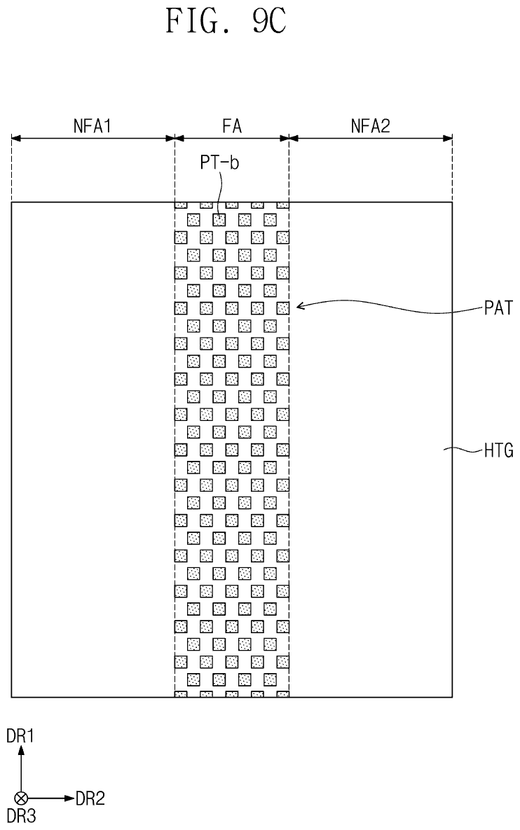

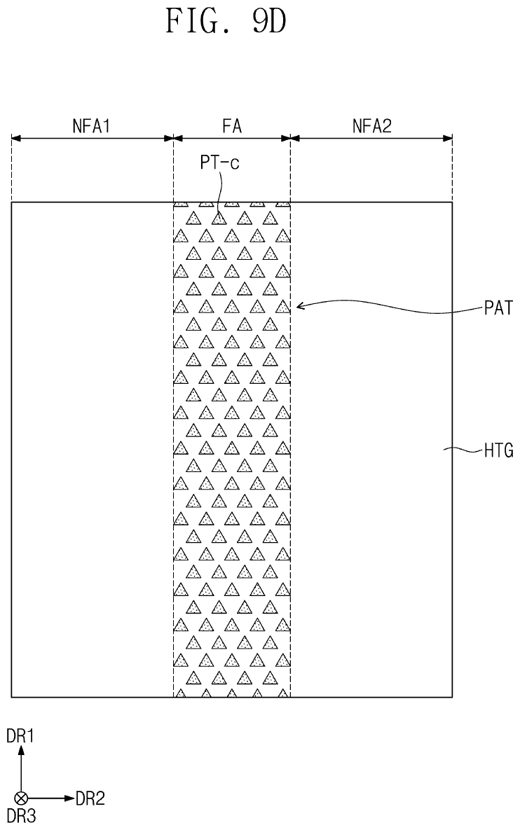

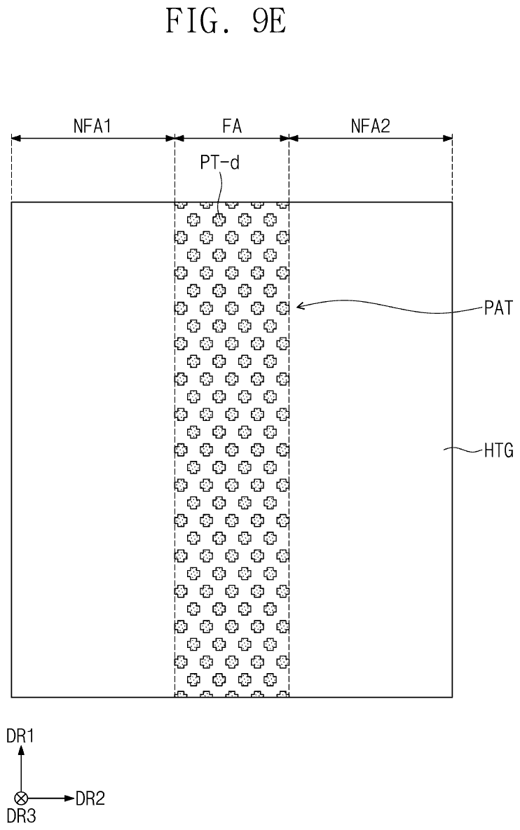

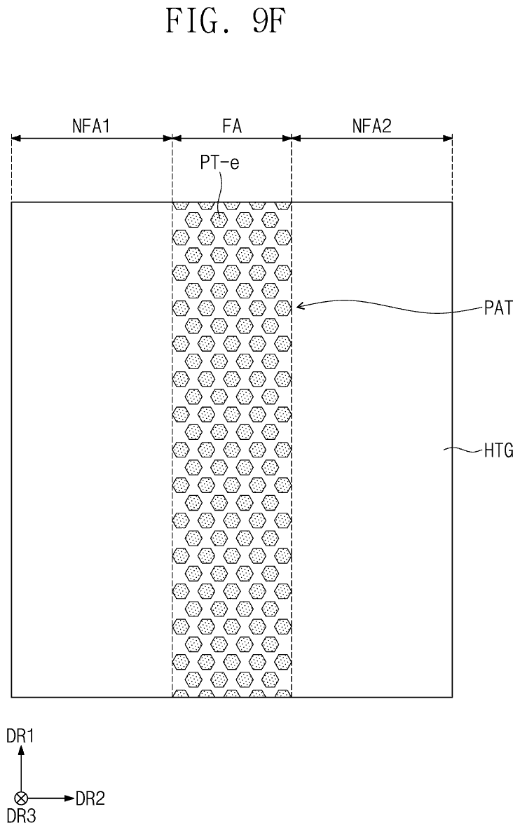

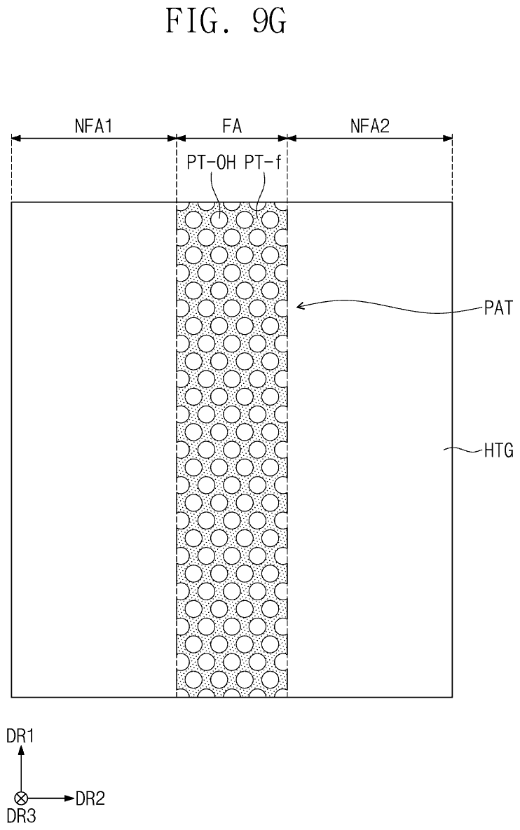

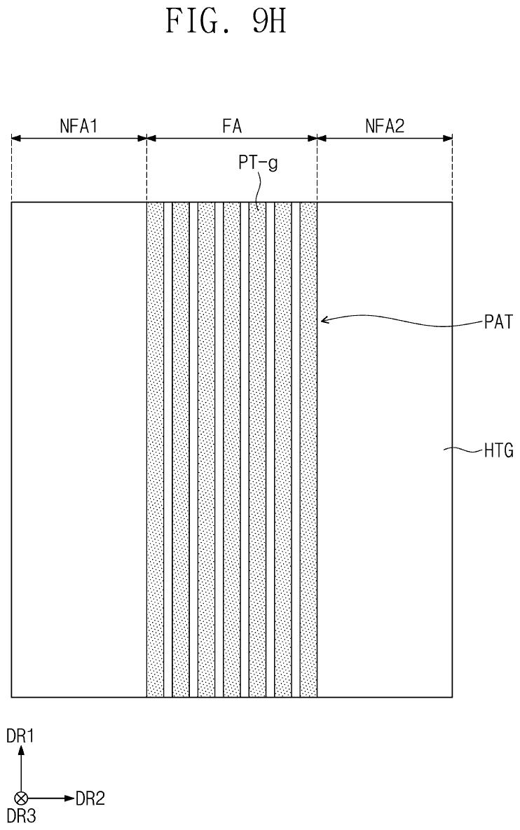

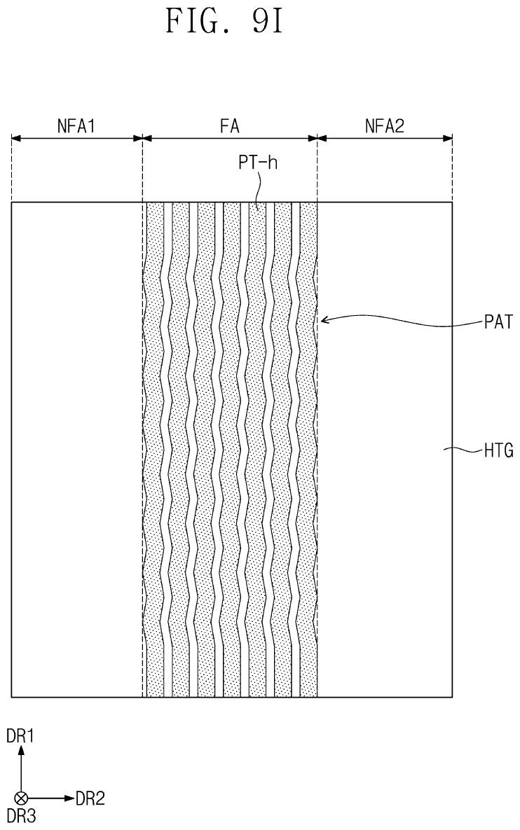

FIGS. 9A to 9I are plan views illustrating an embodiment of the pattern part PAT and the glass substrate HTG. The pattern part PAT may include a plurality of pattern portions PT.

In FIG. 9A, each of the plurality of pattern portions PT may have a quadrangular shape, e.g., rectangular shape. Short sides of the quadrangular shape, e.g., rectangular shape may be parallel to the second direction DR2, and long sides of the quadrangular shape, e.g., rectangular shape may be parallel to the first direction DR1. The short sides of the quadrangular shape, e.g., rectangular shapes may not be parallel to each other in the second direction DR2. The short sides of each of the plurality of pattern portions PT arranged in a first column may not be parallel to the short sides of each of the plurality of pattern portions PT arranged in a second column. The short sides of each of the plurality of pattern portions PT arranged in the first column may be parallel to the short sides of each of the plurality of pattern portions PT arranged in a third column. The short sides of each of the plurality of pattern portions PT arranged in the second column may be parallel to the short sides of each of the plurality of pattern portions PT arranged in a fourth column.

However, this is merely one of embodiments, and arrangement of the quadrangular shape, e.g., rectangular shapes is not limited thereto. Further, the shape of the pattern portion PT in a plan view is not limited to the illustration and may be defined in a shape different from the illustration.

Referring to FIG. 9B, in a plan view, each of a plurality of pattern portions PT-a may have a circular shape. Referring to FIG. 9C, in a plan view, each of a plurality of pattern portions PT-b may have a square shape. Referring to FIG. 9D, in a plan view, each of a plurality of pattern portions PT-c may have a triangular shape. Referring to FIG. 9E, in a plan view, each of a plurality of pattern portions PT-d may have a cross shape. Referring to FIG. 9F, in a plan view, each of a plurality of pattern portions PT-e may have a hexagonal shape. In FIGS. 9B to 9F, the plurality of pattern portions PT-a to PT-e may be arranged not to be parallel in a first row and a second row next (adjacent) to each other. That is, the pattern portions PT-a to PT-e arranged in the first row may be arranged not to be parallel to but to cross the pattern portions PT-a to PT-e arranged in the second row.

Unlike the illustration in FIGS. 9A to 9F, it is illustrated in FIG. 9G that a plurality of pattern portions PT-f have an integral shape in FIG. 9G. plurality of pattern portions PT-f may have an integral shape in a plan view. Openings PT-OH may be defined in the plurality of pattern portions PT-f in a plan view. Referring to FIG. 9G, in a plan view, the openings PT-OH may have a circular shape. Unlike the illustration, the openings PT-OH may have a polygonal shape or a cross shape.

Referring to FIG. 9H, in a plan view, each of a plurality of pattern portions PT-g may have a quadrangular shape, e.g., rectangular shape extending in the first direction DR1. In a plan view, the plurality of pattern portions PT-g may be spaced apart from each other in the second direction DR2.

Referring to FIG. 9I, in a plan view, each of a plurality of pattern portions PT-h may extend in the first direction DR1 and have a curvature. In a plan view, an edge of each of the plurality of pattern portions PT-h may have a curved shape. In a plan view, the plurality of pattern portions PT-h may be spaced apart from each other in the second direction DR2.

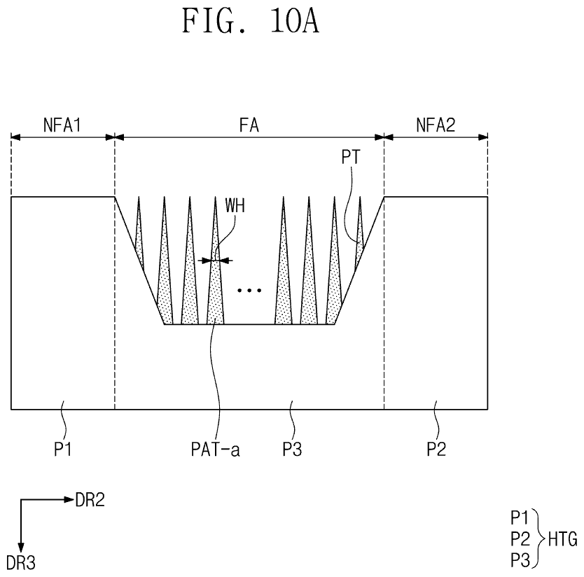

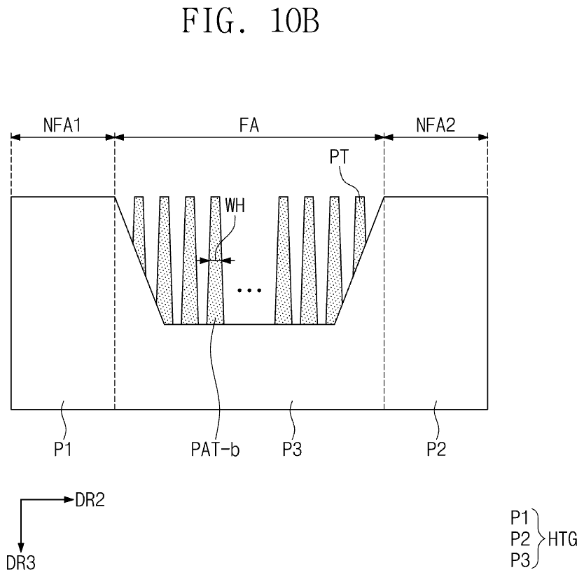

FIGS. 10A and 10B are cross-sectional views illustrating an embodiment of a partial configuration of a window. For convenience of description, FIGS. 10A and 10B illustrate only a glass substrate and a pattern part.

FIGS. 10A and 10B is different from FIGS. 5 to 8 in that a width WH of pattern parts PAT-a and PAT-b decreases as a distance from the glass substrate HTG increases. The width WH of each of the plurality of pattern portions PT included in the pattern parts PAT-a and PAT-b may decrease as a distance from the glass substrate HTG increases. However, this is merely one of embodiments, and the shape of the pattern part in a cross-section is not limited to the illustration and may be defined in a shape different from the illustration.

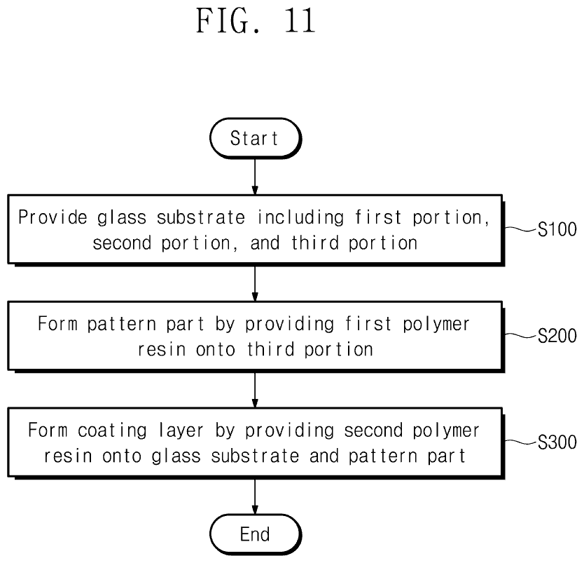

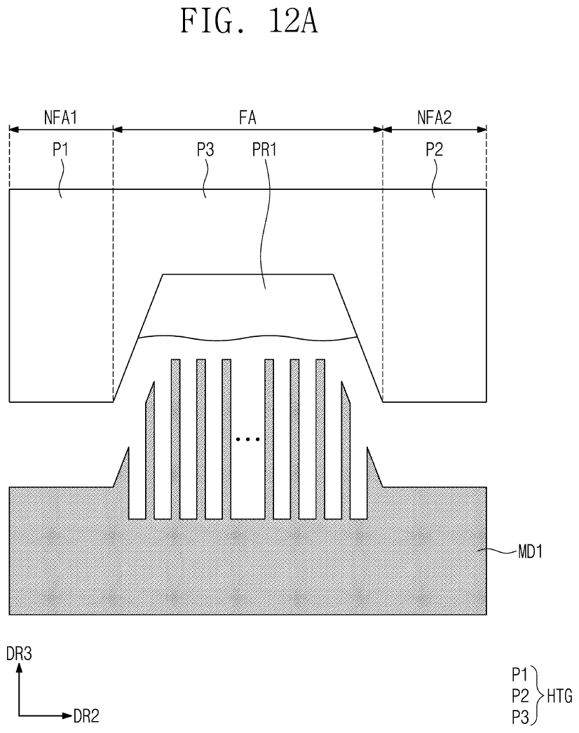

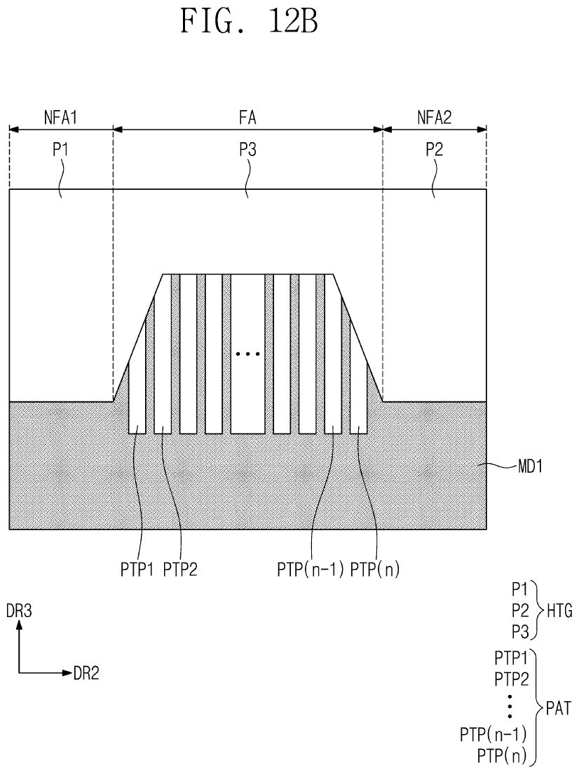

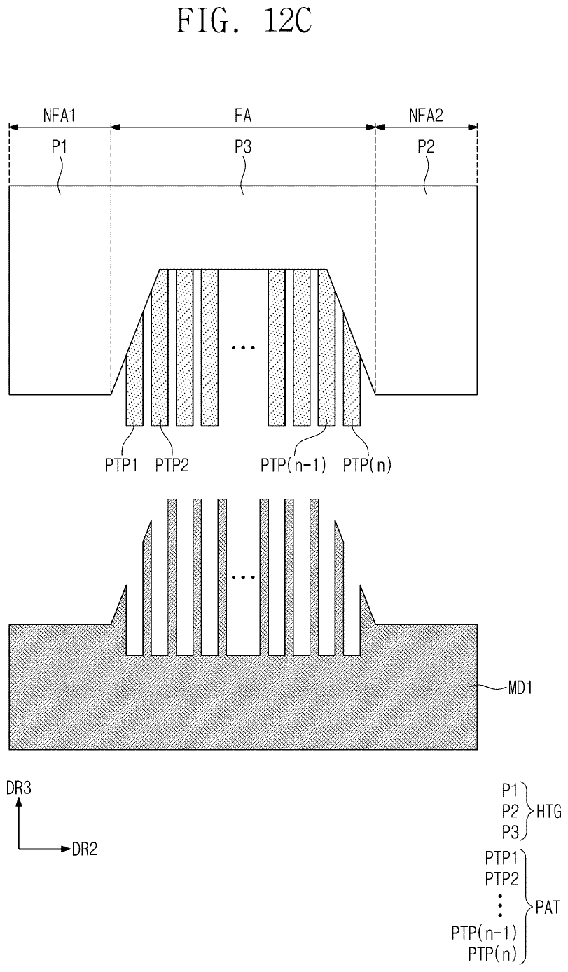

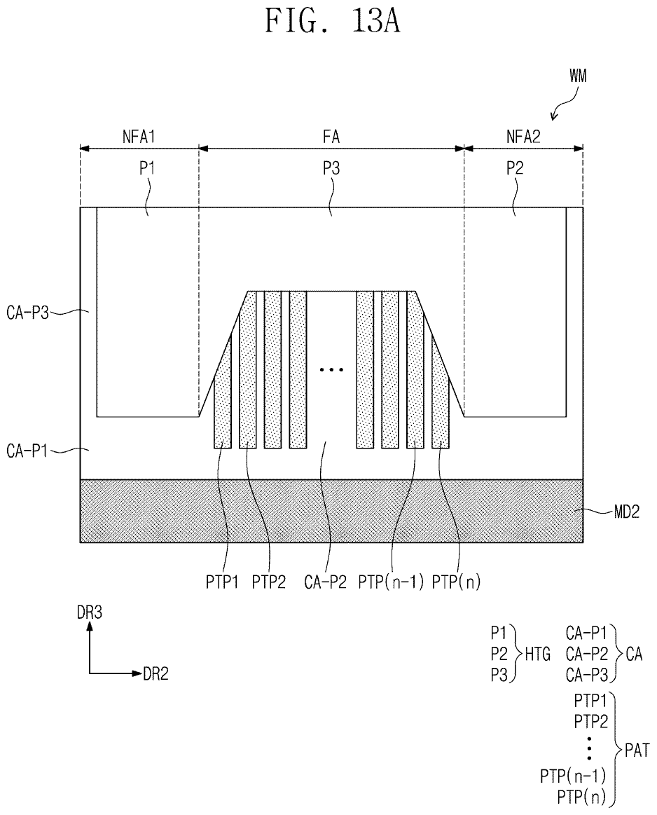

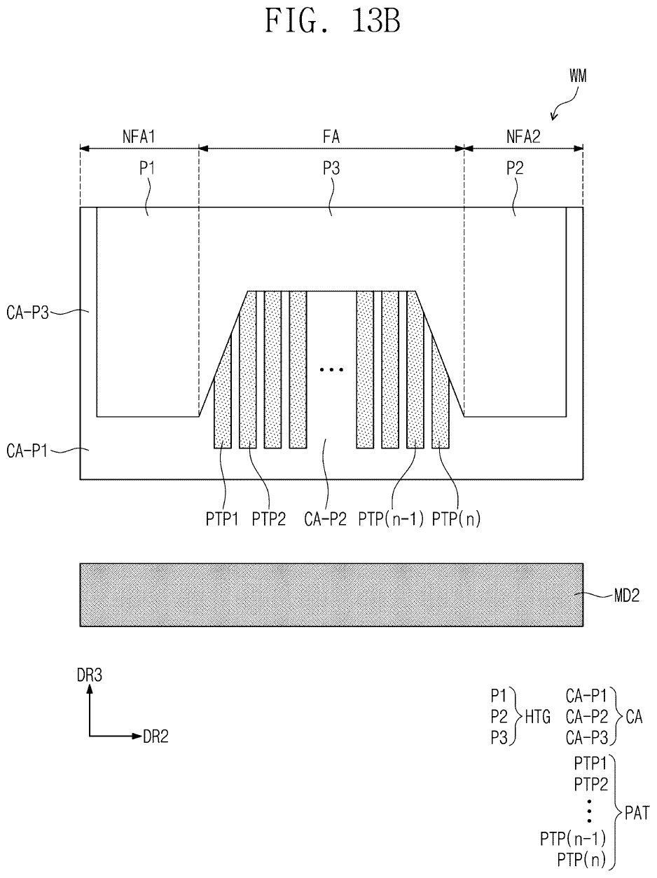

The window WM in an embodiment may be manufactured by a method of manufacturing a window. FIG. 11 is a flowchart illustrating a method of manufacturing a window to an embodiment. FIGS. 12A to 12C, 13A, and 13B are schematic views illustrating the method of manufacturing a window. Hereinafter, in description of FIGS. 11 to 13B, contents duplicated with the contents described with reference to FIGS. 1 to 10B will not be described again, and differences will be mainly described.

Referring to FIG. 11, the method of manufacturing a window in an embodiment may include operation S100 of providing a glass substrate including a first portion, a second portion, and a third portion, operation S200 of forming a pattern part by providing a first polymer resin onto the third portion, and operation S300 of forming a coating layer by providing a second polymer resin onto the glass substrate and the pattern part.

Referring to FIG. 12A, a first polymer resin PR1 may be provided onto one surface of the glass substrate HTG. One surface of the glass substrate HTG may be a lower surface of the glass substrate HTG, which is next (adjacent) to the display module DM (refer to FIG. 4A). The first polymer resin PR1 may be provided to overlap the third portion P3. The first polymer resin PR1 may include at least one of a urethane acrylate-based resin, an epoxy-based resin, and a silicone-based resin. Referring to FIGS. 12B and 12C, a first mold MD1 may be provided, the first polymer resin PR1 may be patterned, and thus the pattern part PAT may be formed. The first mold MD1 may have a plurality of grooves defined therein, and when the first mold MD1 is provided, the first polymer resin PR1 may be introduced into the grooves, and thus the pattern part PAT having a desired shape may be formed. Unlike this, the first polymer resin PR1 may be provided in an inkjet printing method, and thus the pattern part PAT having a desired shape may be formed.

In the window WM-b including the sub-pattern portion SUB-PAT (refer to FIG. 7), an operation of forming the pattern part PAT and an operation of forming the sub-pattern portion SUB-PAT (refer to FIG. 7) may be performed in the same operation. The sub-pattern portion SUB-PAT (refer to FIG. 7) may be formed by providing the first polymer resin PR1. The sub-pattern portion SUB-PAT may include at least one of a urethane acrylate-based resin, an epoxy-based resin, and a silicone-based resin.

Referring to FIGS. 13A and 13B, the coating layer CA may be formed after the pattern part PAT is formed. The second polymer resin for forming the coating layer CA may be provided onto the glass substrate HTG and the pattern part PAT. The second polymer resin may include at least one of a urethane acrylate-based resin, an epoxy-based resin, and a silicone-based resin. The second polymer resin may include a material different from that of the first polymer resin PR1. A second mold MD2 may be provided on the second polymer resin provided on the glass substrate HTG and the pattern part PAT. A lower surface and an upper surface of the second mold MD2, which face each other, may be flat. Accordingly, the lower surface BL (refer to FIG. 5) of the coating layer CA may be formed as a flat surface.

A display panel and an electronic device including the same in an embodiment may include a pattern part overlapping a folding area, thereby exhibiting excellent impact resistance.

A method of manufacturing a window in an embodiment may include an operation of forming a pattern part and a coating layer and thus manufacture a window exhibiting excellent impact resistance.

Although the description has been made above with reference to an embodiment of the disclosure, it may be understood that those skilled in the art or those having ordinary knowledge in the art may variously modify and change the disclosure without departing from the spirit and technical scope of the disclosure described in the appended claims.

Accordingly, the technical scope of the disclosure is not limited to the detailed description of the specification, but should be defined by the appended claims.

What is claimed is:

1. A window divided into a folding area, a first non-folding area next to a side of the folding area, and a second non-folding area next to an opposite side of the folding area opposite to the side of the folding area, the window comprising:
a coating layer having a first Young's modulus;
a glass substrate disposed on the coating layer, the glass substrate including:
a first portion overlapping the first non-folding area;
a second portion overlapping the second non-folding area; and
a third portion overlapping the folding area and having a thickness smaller than a thickness of the first portion and the second portion; and
a pattern part disposed between the coating layer and the glass substrate, overlapping the folding area, and having a second Young's modulus greater than the first Young's modulus, the pattern part including:
a plurality of pattern portions spaced apart from each other in a direction perpendicular to a thickness direction, the plurality of pattern portions including:
a first pattern portion having a first length in the thickness direction; and
a second pattern portion having a second length greater than the first length and spaced apart from the first pattern portion in the direction.

2. The window of claim 1, wherein the pattern part does not overlap the first non-folding area and the second non-folding area.

3. The window of claim 1, wherein the first pattern portion is disposed outside the second pattern portion.

4. The window of claim 1, wherein an upper surface of each of the first pattern portion and the second pattern portion contacts the glass substrate.

5. The window of claim 1, wherein the coating layer includes a first coating portion extending in the direction and a second coating portion extending from the first coating portion and filling gaps between the plurality of pattern portions.

6. The window of claim 5, wherein the coating layer further includes a third coating portion extending from the first coating portion and disposed next to a side surface of the glass substrate.

7. The window of claim 1, further comprising:
a sub-pattern portion disposed on the coating layer and having the first Young's modulus,
wherein the sub-pattern portion is spaced apart from the pattern part in the direction, and
wherein the glass substrate is interposed between the sub-pattern portion and the pattern part.

8. The window of claim 1, wherein, in a plan view, each of the plurality of pattern portions has a circular shape, a polygonal shape, or a cross shape.

9. The window of claim 1, wherein the plurality of pattern portions have an integral shape, and in a plan view, openings are defined in the plurality of pattern portions.

10. The window of claim 1, wherein, in a plan view, each of the plurality of pattern portions has a curvature and extends in an other direction perpendicular to the direction.

11. The window of claim 1, wherein a width of each of the plurality of pattern portions in the direction decreases as a distance from the glass substrate increases.

12. The window of claim 1, wherein the first Young's modulus of the coating layer is greater than or equal to 0.1 gigapascal and smaller than 1 gigapascal.

13. The window of claim 1, wherein the second Young's modulus of the pattern part is greater than or equal to 1 gigapascal and smaller than or equal to 10 gigapascal.

14. The window of claim 1, wherein each of the pattern part and the coating layer includes at least one of a urethane acrylate-based resin, an epoxy-based resin, and a silicone-based resin.

15. The window of claim 1, wherein the coating layer includes an upper surface next to the glass substrate and a lower surface spaced apart from the glass substrate,
wherein the upper surface is interposed between the lower surface and the glass substrate, and
wherein the lower surface is a flat surface.

16. A method of manufacturing a window which is divided into a folding area, a first non-folding area next to a side of the folding area, and a second non-folding area next to an opposite side of the folding area opposite to the side of the folding area and includes a coating layer, a glass substrate disposed on the coating layer, and a pattern part disposed between the coating layer and the glass substrate, the method comprising:
preparing the glass substrate including a first portion overlapping the first non-folding area, a second portion overlapping the second non-folding area, and a third portion overlapping the folding area and having a thickness smaller than those of the first portion and the second portion;
forming the pattern part including a plurality of pattern portions by providing a first polymer resin onto the third portion; and
forming the coating layer by providing a second polymer resin onto the glass substrate and the pattern part,
wherein the plurality of pattern portions are spaced apart from each other in a direction perpendicular to a thickness direction and includes a first pattern portion having a first length in the thickness direction and a second pattern portion having a second length smaller than the first length and spaced apart from the first pattern portion in the direction, and
wherein a second Young's modulus of the pattern part is greater than a first Young's modulus of the coating layer.

17. The method of claim 16, wherein the forming the pattern part includes patterning the first polymer resin provided on the third portion using a first mold.

18. The method of claim 16, wherein the forming the pattern part includes patterning the first polymer resin in an inkjet printing method.

19. The method of claim 16, wherein, in the forming the coating layer, a second mold is provided to the second polymer resin provided onto the glass substrate and the pattern part,
wherein the coating layer includes an upper surface next to the glass substrate and a flat lower surface which is spaced apart from the glass substrate, and
wherein the upper surface is interposed between the flat lower surface and the glass substrate.

20. An electronic device comprising:
a display module; and
a window disposed on the display module and divided into a folding area, a first non-folding area next to a side of the folding area, and a second non-folding area next to an opposite side of the folding area opposite to the side of the folding area, the window including:
a coating layer having a first Young's modulus;
a glass substrate disposed on the coating layer, the glass substrate including:
a first portion overlapping the first non-folding area;
a second portion overlapping the second non-folding area; and
a third portion overlapping the folding area and having a thickness smaller than a thickness of the first portion and the second portion; and
a pattern part disposed between the coating layer and the glass substrate, overlapping the folding area, and having a second Young's modulus greater than the first Young's modulus, the pattern part including:
a plurality of pattern portions spaced apart from each other in one direction perpendicular to a thickness direction, the plurality of pattern portions including:
a first pattern portion having a first length in the thickness direction; and
a second pattern portion having a second length smaller than the first length and spaced apart from the first pattern portion in the direction.
